(19) United States
(12) Patent Application Publication
(10) Pub. No.: US 2026/0278233 A1
(43) Pub. Date: Sep. 17, 2026

(54) CIRCUIT DESIGN METHOD, CIRCUIT DESIGN DEVICE, AND NON-TRANSITORY COMPUTER READABLE STORAGE MEDIUM

(71) Applicant: REALTEK SEMICONDUCTOR CORPORATION, HSINCHU (TW)

(72) Inventor: CHENG-CHEN HUANG, HSINCHU (TW)

(21) Appl. No.: 19/561,937

(22) Filed: Mar. 10, 2026

(30) Foreign Application Priority Data
Mar. 12, 2025 (TW) 114109086

(51) Int. Cl. G06F 30/392; G06F 30/398

(52) U.S. Cl. CPC G06F 30/392; G06F 30/398

(57) ABSTRACT

A circuit design method, a circuit design device, and a non-transitory computer readable storage medium are disclosed herein. The circuit design method is executed by a processor reading at least command stored in a memory. The circuit design method includes: providing a plurality of via pillar arrangements, wherein each of the plurality of via pillar arrangements includes a via pillar number and a via pillar spacing; providing a plurality of standard cells; calculating a plurality of pin overlapping numbers of each of the plurality of via pillar arrangements and the plurality of standard cells; and selecting a via pillar arrangement corresponding to a minimum pin overlapping number among the plurality of pin overlapping numbers as a target via pillar arrangement.

### BACKGROUND OF THE INVENTION

### 1. Field of the Invention

The present disclosure relates to a circuit design method, a circuit design device, and a non-transitory computer readable storage medium, especially to a circuit design method, a circuit design device, and a non-transitory computer readable storage medium for improving a pin accessibility area and routability.

### 2. Description of Related Art

During a circuit development process, for the completeness of a power mesh and subsequent adjustability, a power mesh and via pillars are mostly generated before a placement stage and a routing stage. However, the power mesh and the via pillars share routing resources of metal layers with signal routing, and thus are likely to obstruct a pin accessibility area and routability of pins in standard cells.

Although standard cells may be slightly adjusted in position during a placement stage of a circuit, or a number of via pillars may be reduced during power planning so as to increase the pin accessibility area and the routability, the positions that may be adjusted and the routability are relatively limited in an area where high-density standard cells are placed. In addition, reducing the number of via pillars during power planning results in a more serious IR drop and electromigration, thereby affecting performance and reliability of an integrated circuit (IC).

### SUMMARY OF THE INVENTION

In some aspects, an object of the present disclosure is to, but not limited to, provide a circuit design method, a circuit design device, and a non-transitory computer readable storage medium that make an improvement to the prior art.

In some embodiments, a circuit design method is executed by a processor reading at least command stored in a memory. The circuit design method includes: providing a plurality of via pillar arrangements, wherein each of the plurality of via pillar arrangements includes a via pillar number and a via pillar spacing; providing a plurality of standard cells; calculating a plurality of pin overlapping numbers of each of the plurality of via pillar arrangements and the plurality of standard cells; and selecting a via pillar arrangement corresponding to a minimum pin overlapping number among the plurality of pin overlapping numbers as a target via pillar arrangement.

In some embodiments, a circuit design device includes a memory and a processor. The memory is configured to store at least one command. The processor is configured to read the at least one command in the memory to execute: providing a plurality of via pillar arrangements, wherein each of the plurality of via pillar arrangements includes a via pillar number and a via pillar spacing; providing a plurality of standard cells; calculating a plurality of pin overlapping numbers of each of the plurality of via pillar arrangements and the plurality of standard cells; and selecting a via pillar arrangement corresponding to a minimum pin overlapping number among the plurality of pin overlapping numbers as a target via pillar arrangement.

In some embodiments, a non-transitory computer readable storage medium storing a computer program is provided, wherein the computer program is configured to execute a circuit design method, and the circuit design method includes: providing a plurality of via pillar arrangements, wherein each of the plurality of via pillar arrangements includes a via pillar number and a via pillar spacing; providing a plurality of standard cells; calculating a plurality of pin overlapping numbers of each of the plurality of via pillar arrangements and the plurality of standard cells; and selecting a via pillar arrangement corresponding to a minimum pin overlapping number among the plurality of pin overlapping numbers as a target via pillar arrangement.

Technical features of some embodiments of the present disclosure make an improvement to the prior art. The circuit design method, the circuit design device, and the non-transitory computer-readable recording medium of the present disclosure may increase a pin accessibility area and routability without needing to reduce a number of via pillars.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of a circuit design device of the present disclosure.

FIG. 2 shows an embodiment of a flow diagram of a circuit design method of the present disclosure.

FIG. 3 shows an embodiment of a relation between a via pillar and a standard cell of the present disclosure.

FIG. 4 shows an embodiment of a relation between a via pillar and a standard cell of the present disclosure.

FIG. 5 shows an embodiment of a relation between a via pillar and a standard cell of the present disclosure.

FIG. 6 shows an embodiment of a relation between a via pillar and a standard cell of the present disclosure.

FIG. 7 shows an embodiment of a relation between a via pillar and a standard cell of the present disclosure.

FIG. 8 shows an embodiment of a relation between a via pillar and a standard cell of the present disclosure.

FIG. 9 shows an embodiment of a relation between a via pillar and a standard cell of the present disclosure.

FIG. 10 shows an embodiment of a relation between a via pillar and a standard cell of the present disclosure.

FIG. 11 shows an embodiment of a relation between a via pillar and a standard cell of the present disclosure.

FIG. 12 shows an embodiment of a relation between a via pillar and a standard cell of the present disclosure.

FIG. 13 shows an embodiment of a relation between a via pillar and a standard cell of the present disclosure.

FIG. 14 shows an embodiment of a relation between a via pillar and a standard cell of the present disclosure.

FIG. 15 shows an embodiment of a relation between a via pillar and a standard cell of the present disclosure.

FIG. 16 shows an embodiment of a relation between a via pillar and a standard cell of the present disclosure.

FIG. 17 shows an embodiment of a relation between a via pillar and a standard cell of the present disclosure.

FIG. 18 shows an embodiment of a relation between a via pillar and a standard cell of the present disclosure.

FIG. 19 shows an embodiment of a relation between a via pillar and a standard cell of the present disclosure.

FIG. 20 shows an embodiment of a relation between a via pillar and a standard cell of the present disclosure.

### DETAILED DESCRIPTION OF THE PREFERRED EMBODIMENTS

To improve the problem that both an adjustable position and a routability are relatively limited in a placement region of high-density standard cells, and to improve the problem that reducing a number of via pillars causes more severe IR drop and electromigration, the present disclosure provides a circuit design method, a circuit design device, and a non-transitory computer readable storage medium. Detailed descriptions are given below.

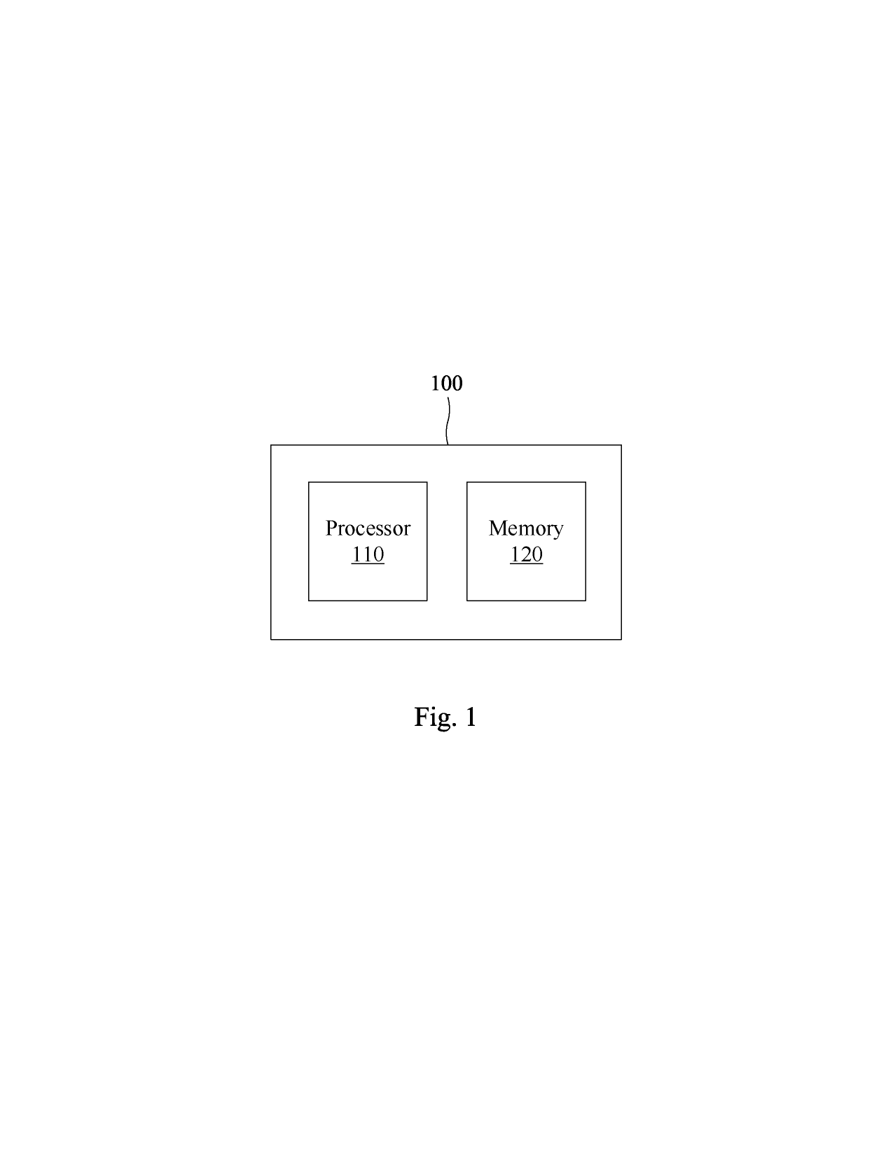

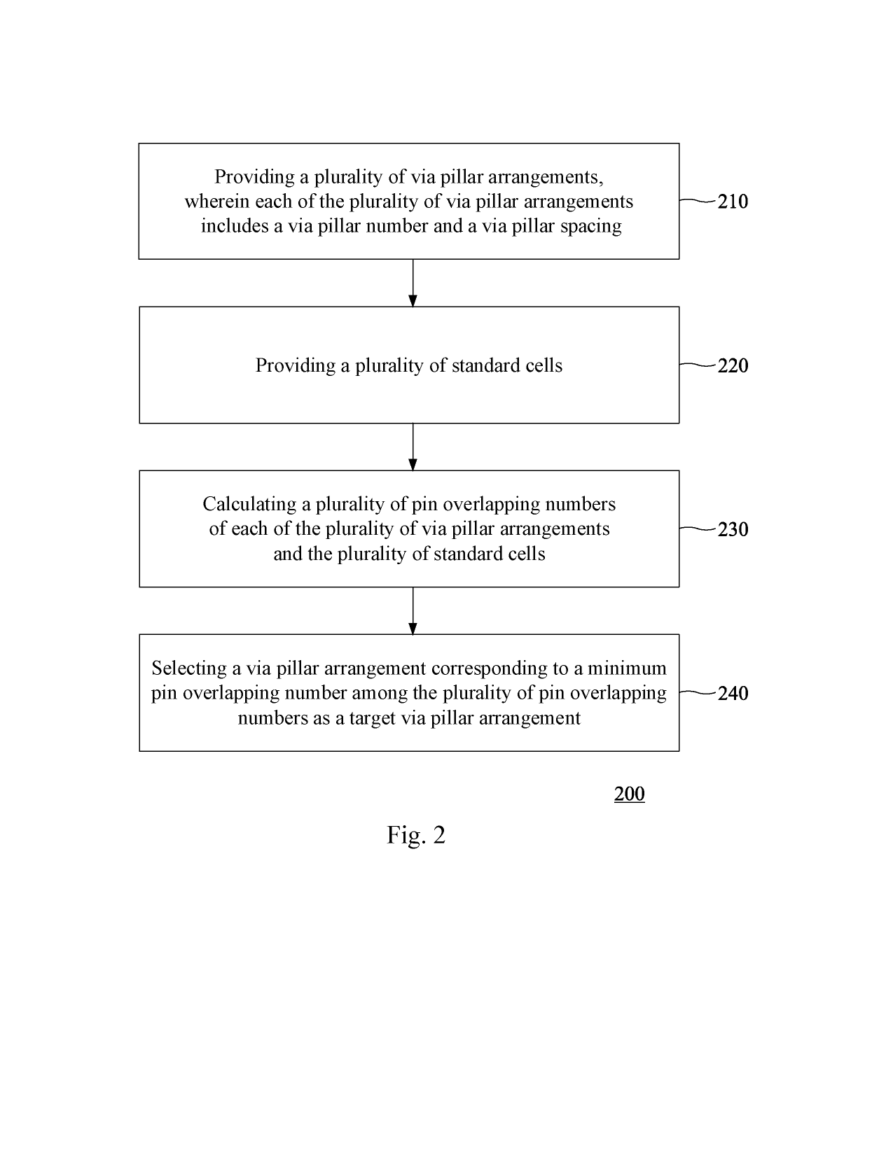

FIG. 1 shows an embodiment of a circuit design device 100 of the present disclosure. As shown in the figure, the circuit design device 100 includes a processor 110 and a memory 120. The memory 120 is configured to store at least one command. The processor bis configured to read the at least one command to perform a circuit design process. To facilitate understanding of the operation of the circuit design device 100, please also refer to FIG. 2. FIG. 2 shows an embodiment of a flow diagram of a circuit design method 200 of the present disclosure.

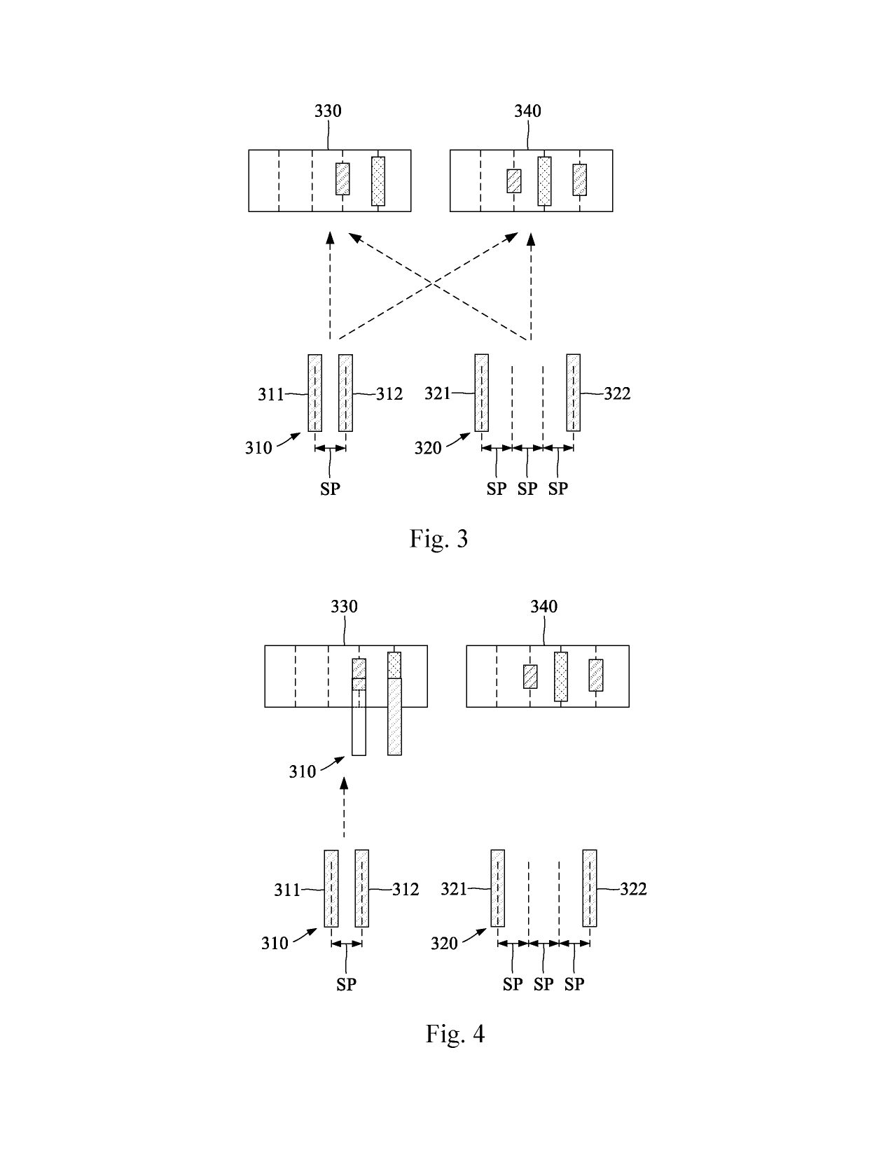

Referring to step 210 in FIG. 2, providing a plurality of via pillar arrangements, wherein each of the plurality of via pillar arrangements includes a via pillar number and a via pillar spacing. For example, referring to FIG. 3, the circuit design method 200 of the present disclosure provides a first via pillar arrangement set 310 and a second via pillar arrangement set 320. The first via pillar arrangement set 310 includes two via pillars 311, 312, and therefore a via pillar number of the first via pillar arrangement set 310 is two. In addition, a distance between the via pillars 311, 312 is one via pillar spacing SP.

Furthermore, the second via pillar arrangement set 320 includes two via pillars 321, 322, and therefore a via pillar number of the second via pillar arrangement set 320 is two. In addition, a distance between the via pillars 321, 322 is three via pillar spacings SP. It should be noted that dashed lines on which the via pillars 311, 312, 321, 322 are located represent track positions defined by the circuit design, and each via pillar is required to be placed on the track positions. A spacing between two track positions is one via pillar spacing SP of the present disclosure. However, the present disclosure is not limited to the above embodiment. In other embodiments, the first via pillar arrangement set 310 and the second via pillar arrangement set 320 may further include metal layer information, and the via pillar number and the via pillar spacing of the first via pillar arrangement set 310 and the second via pillar arrangement set 320 may adopt other suitable values, depending on actual requirements.

Referring to step 220 in FIG. 2, providing a plurality of standard cells. For example, referring to FIG. 3, the circuit design method 200 of the present disclosure provides a plurality of standard cells 330, 340.

Referring to step 230 in FIG. 2, calculating a plurality of pin overlapping numbers of each of the plurality of via pillar arrangements and the plurality of standard cells. For example, referring to FIG. 3, the circuit design method 200 of the present disclosure may calculate a first pin overlapping number of the first via pillar arrangement set 310 and the plurality of standard cells 330, 340, and may calculate a second pin overlapping number of the second via pillar arrangement set 320 and the plurality of standard cells 330, 340.

Referring to step 240 in FIG. 2, selecting a via pillar arrangement corresponding to a minimum pin overlapping number among the plurality of pin overlapping numbers as a target via pillar arrangement. For example, referring to FIG. 3, the circuit design method 200 of the present disclosure may compare the first pin overlapping number between the first via pillar arrangement set 310 and the plurality of standard cells 330, 340 with the second pin overlapping number between the second via pillar arrangement set 320 and the plurality of standard cells 330, 340. If the first pin overlapping number is smaller than the second pin overlapping number, the first via pillar arrangement set 310 corresponding to the first pin overlapping number is selected as the target via pillar arrangement.

In some embodiments, after selecting the first via pillar arrangement set 310 as the target via pillar arrangement, whether the target via pillar arrangement conforms to a design rule is further determined. If the target via pillar arrangement conforms to the design rule, a subsequent circuit design is performed by the target via pillar arrangement. In addition, if the target via pillar arrangement does not conform to the design rule, a next via pillar arrangement corresponding to a next minimum pin overlapping number is sequentially selected until one conforms to the design rule or until none of them conforms.

FIGS. 4 to 11 show embodiments of a relation between a via pillar and a standard cell of the present disclosure. Referring to FIG. 4, an overlapping condition of the via pillar arrangement set 310 with the plurality of standard cells 330, 340 is assigned as overlapping two signal pins. As shown in the figure, the via pillar arrangement set 310 and the standard cell 330 overlap two signal pins, so one overlapping is calculated.

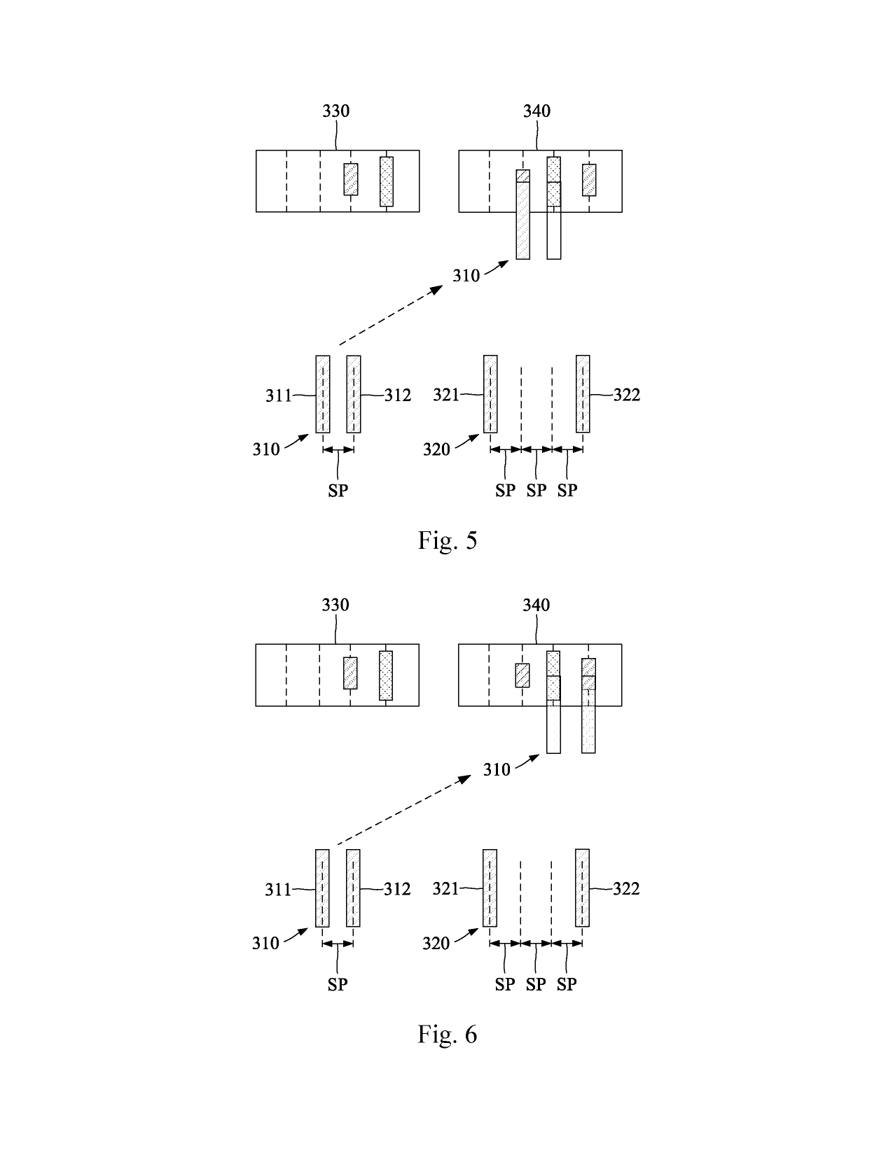

Referring to FIG. 5, the overlapping condition of the via pillar arrangement set 310 with the plurality of standard cells 330, 340 is still assigned as overlapping two signal pins. As shown in the figure, the via pillar arrangement set 310 and the standard cell 340 overlap two signal pins, so one overlapping is calculated.

Referring to FIG. 6, the overlapping condition of the via pillar arrangement set 310 with the plurality of standard cells 330, 340 is still assigned as overlapping two signal pins. As shown in the figure, the via pillar arrangement set 310 and the standard cell 340 overlap two signal pins, so one overlapping is calculated.

In summary, if the overlapping condition of the via pillar arrangement set 310 with the plurality of standard cells 330, 340 is assigned as overlapping two signal pins, then the pin overlapping number of the via pillar arrangement set 310 with the standard cell 330 is one, the pin overlapping number of the via pillar arrangement set 310 with the standard cell 340 is two, and the total pin overlapping number of the via pillar arrangement set 310 with the plurality of standard cells 330, 340 is three.

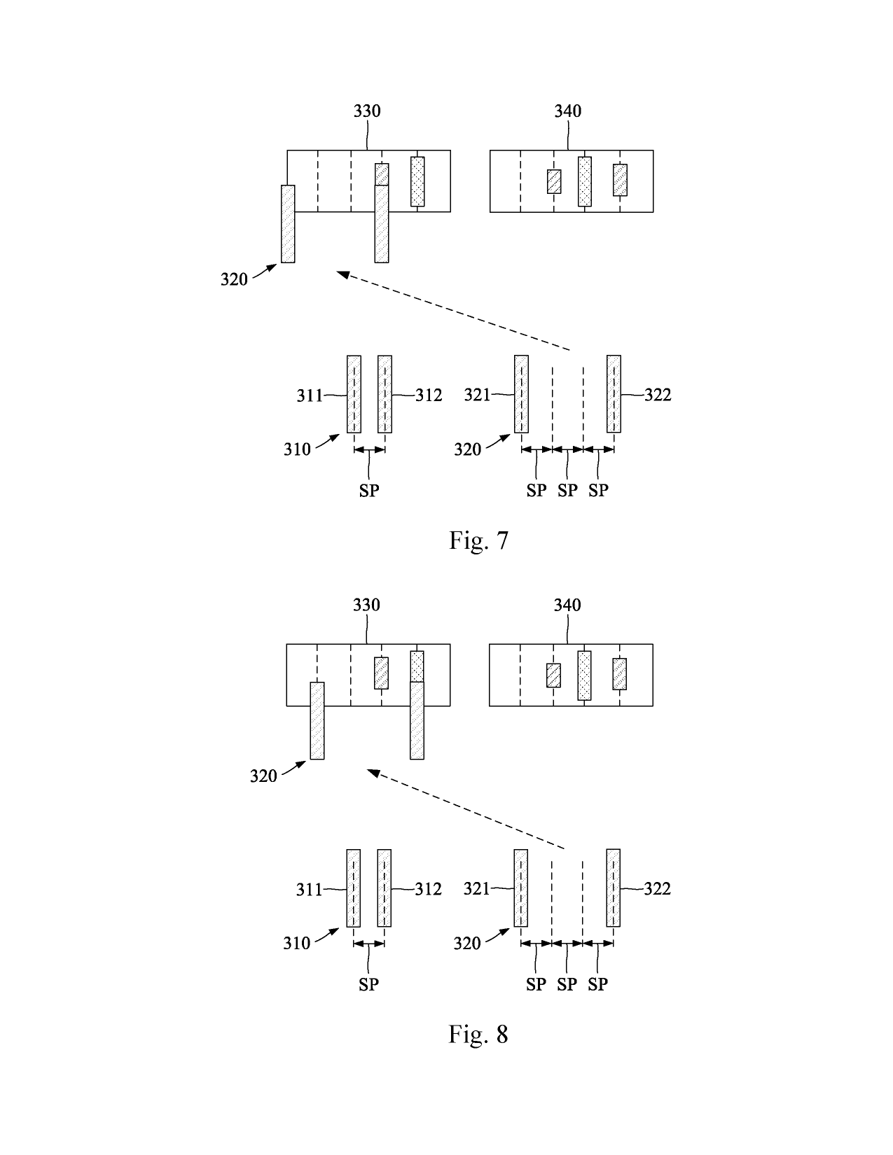

In addition, referring to FIG. 7, the overlapping condition of the via pillar arrangement set 320 with the plurality of standard cells 330, 340 is assigned as overlapping two signal pins. As shown in the figure, the via pillar arrangement set 320 and the standard cell 330 overlap only one signal pin, so zero overlapping is calculated.

Referring to FIG. 8, the overlapping condition of the via pillar arrangement set 320 with the plurality of standard cells 330, 340 is still assigned as overlapping two signal pins. As shown in the figure, the via pillar arrangement set 320 and the standard cell 330 overlap only one signal pin, so zero overlapping is calculated.

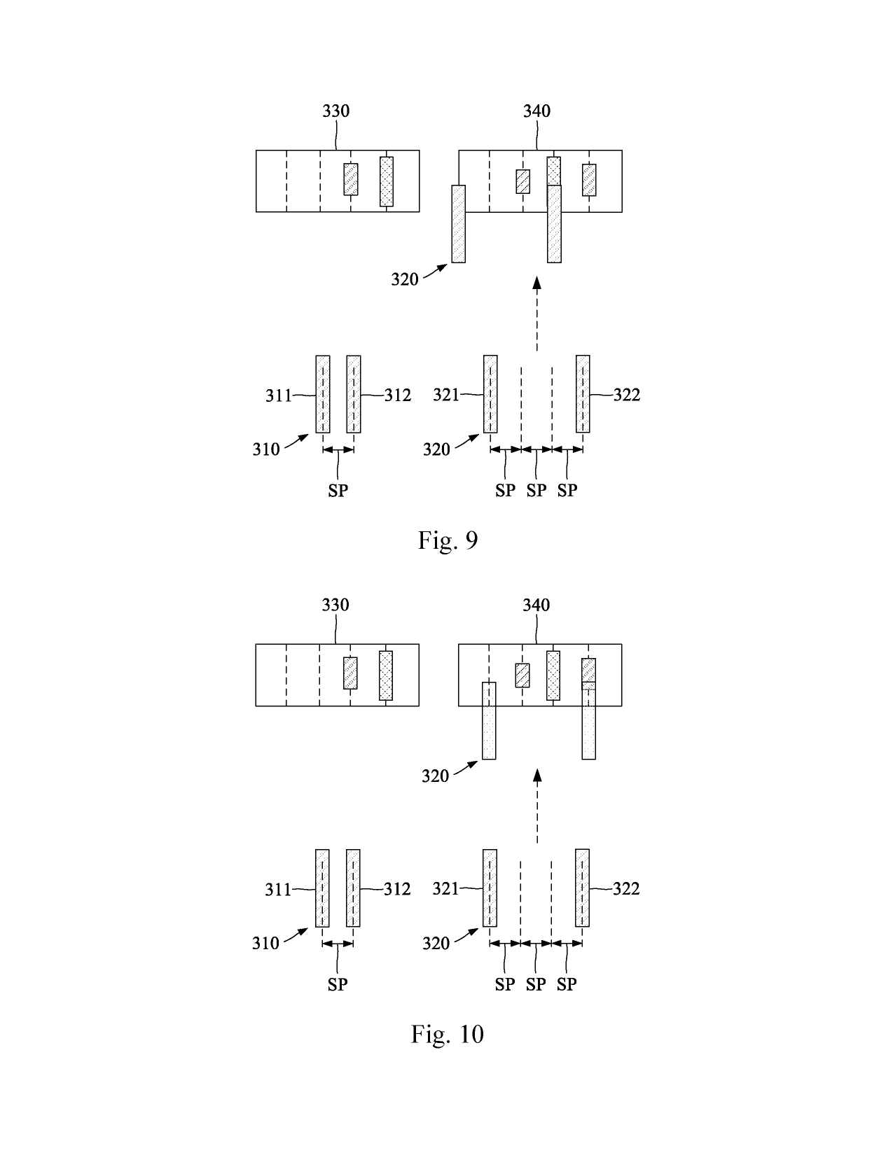

Referring to FIG. 9, the overlapping condition of the via pillar arrangement set 320 with the plurality of standard cells 330, 340 is still assigned as overlapping two signal pins. As shown in the figure, the via pillar arrangement set 320 and the standard cell 340 overlap only one signal pin, so zero overlapping is calculated.

Referring to FIG. 10, the overlapping condition of the via pillar arrangement set 320 with the plurality of standard cells 330, 340 is still assigned as overlapping two signal pins. As shown in the figure, the via pillar arrangement set 320 and the standard cell 340 overlap only one signal pin, so zero overlapping is calculated.

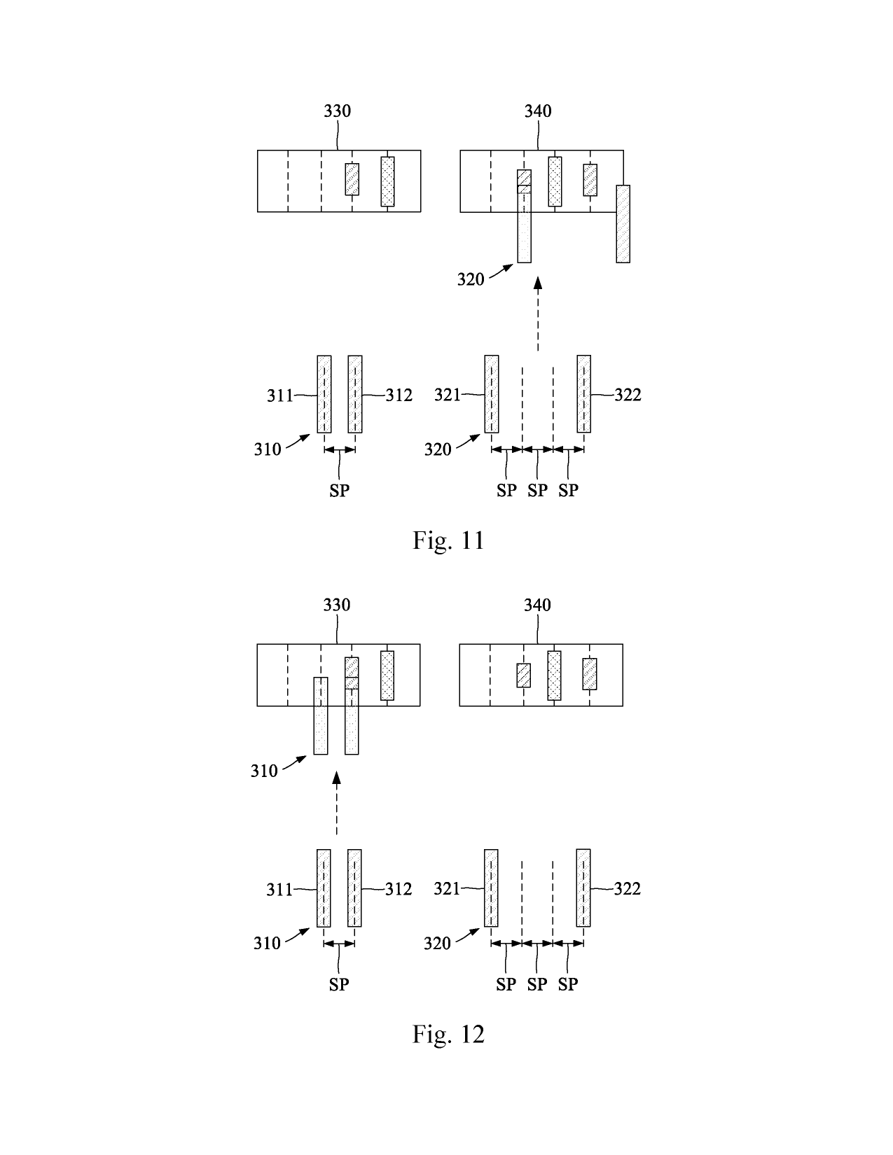

Referring to FIG. 11, the overlapping condition of the via pillar arrangement set 320 with the plurality of standard cells 330, 340 is still assigned as overlapping two signal pins. As shown in the figure, the via pillar arrangement set 320 and the standard cell 340 overlap only one signal pin, so zero overlapping is calculated.

In summary, if the overlapping condition of the via pillar arrangement set 320 with the plurality of standard cells 330, 340 is assigned as overlapping two signal pins, then the pin overlapping number of the via pillar arrangement set 320 with the standard cell 330 is zero, the pin overlapping number of the via pillar arrangement set 320 with the standard cell 340 is zero, and the total pin overlapping number of the via pillar arrangement set 320 with the plurality of standard cells 330, 340 is zero.

Therefore, the pin overlapping number of the via pillar arrangement set 320 with the plurality of standard cells 330, 340 is only zero, while the pin overlapping number of the via pillar arrangement set 310 with the plurality of standard cells 330, 340 is three. The circuit design method 200 of the present disclosure selects the via pillar arrangement set 320 corresponding to the minimum pin overlapping number as the target via pillar arrangement.

The circuit design method 200 of the present disclosure may calculate a plurality of pin overlapping numbers of each of the plurality of via pillar arrangements with the plurality of standard cells according to the overlapping condition and different weights, and the description is as follows. FIG. 12 to FIG. 20 show embodiments of a relation between a via pillar and a standard cell of the present disclosure. Referring to FIG. 12, an overlapping condition of the via pillar arrangement set 310 with the plurality of standard cells 330, 340 is assigned as overlapping one signal pin. The weight of the standard cell 330 is 1, and the weight of the standard cell 340 is 2. As shown in the figure, the via pillar arrangement set 310 and the standard cell 330 overlap one signal pin, so one overlapping is calculated.

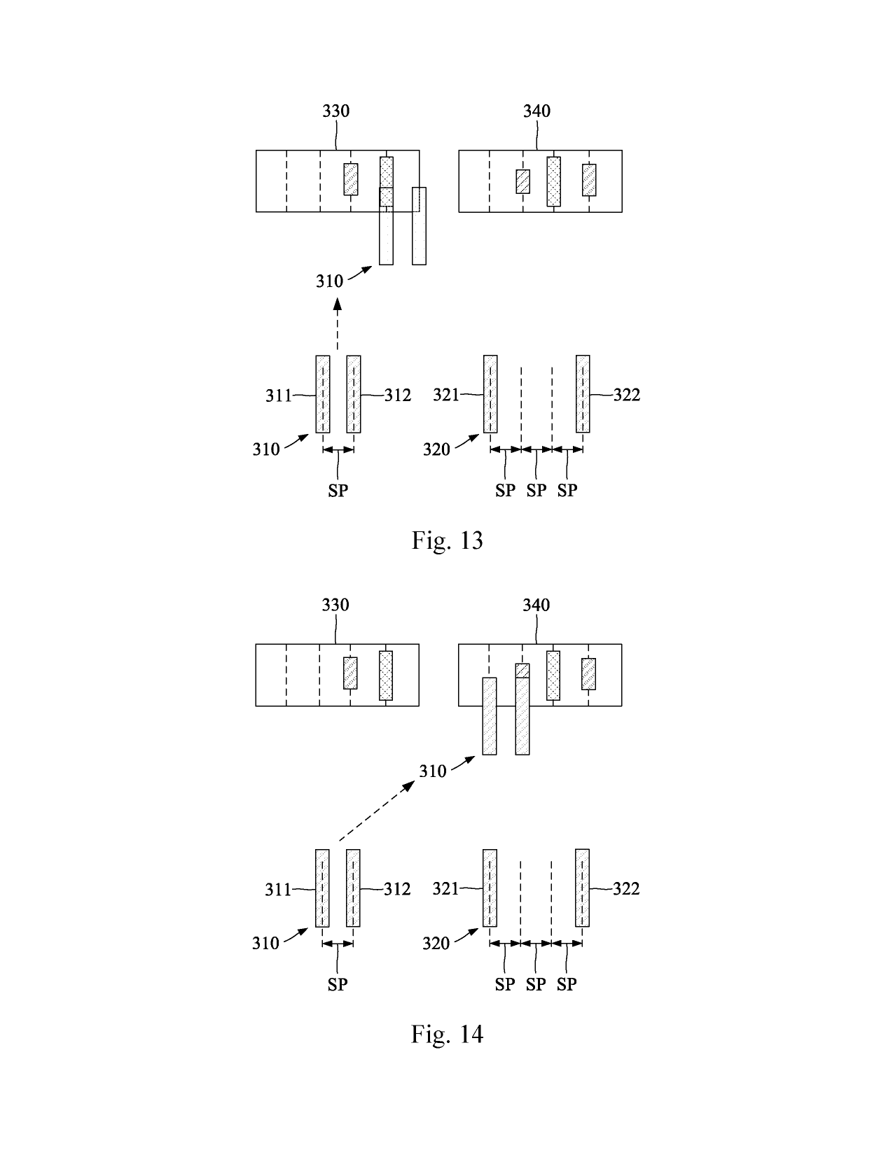

Referring to FIG. 13, the overlapping condition of the via pillar arrangement set 310 with the plurality of standard cells 330, 340 is still assigned as overlapping one signal pin. As shown in the figure, the via pillar arrangement set 310 and the standard cell 330 overlap one signal pin, so one overlapping is calculated.

Referring to FIG. 14, the overlapping condition of the via pillar arrangement set 310 with the plurality of standard cells 330, 340 is still assigned as overlapping one signal pin. As shown in the figure, the via pillar arrangement set 310 and the standard cell 340 overlap one signal pin, so one overlapping is calculated. Since the weight of the standard cell 340 is 2, one overlapping is multiplied by the weight 2, resulting in two overlappings.

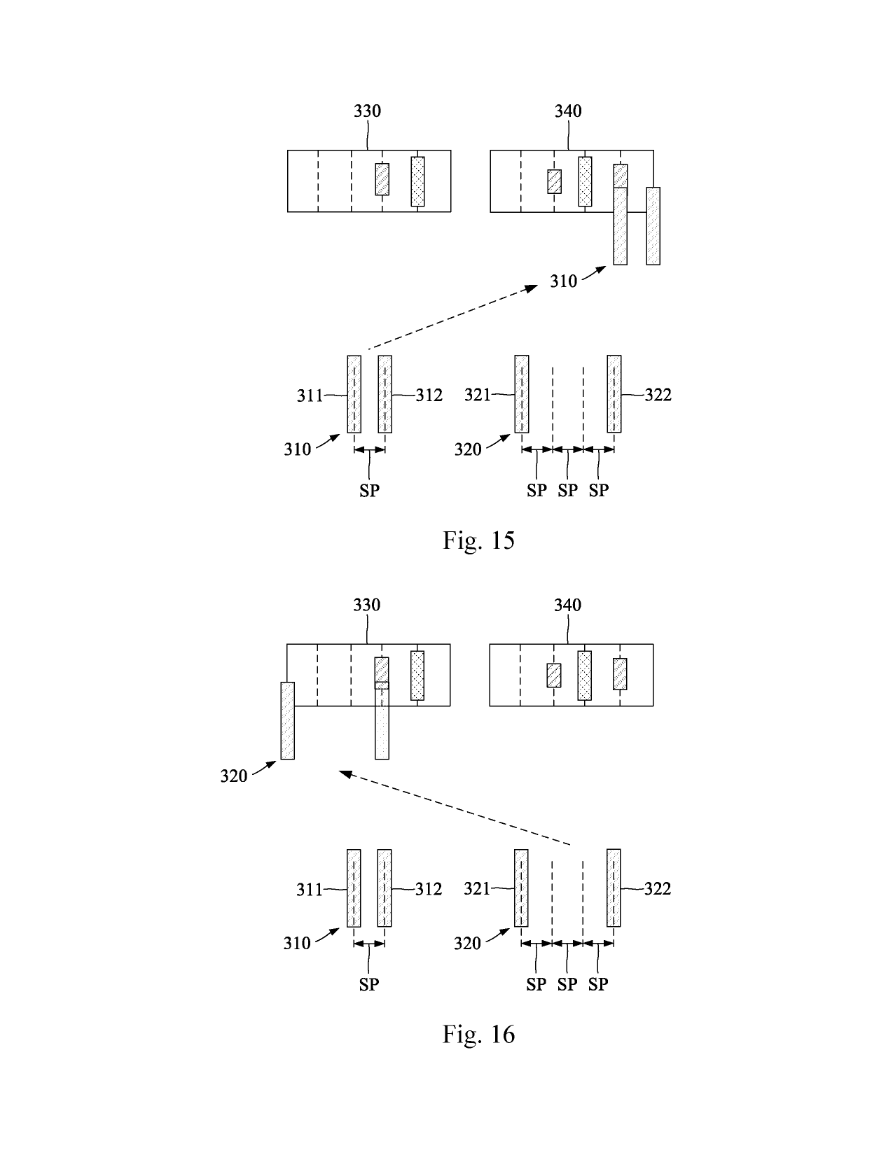

Referring to FIG. 15, the overlapping condition of the via pillar arrangement set 310 with the plurality of standard cells 330, 340 is still assigned as overlapping one signal pin. As shown in the figure, the via pillar arrangement set 310 and the standard cell 340 overlap one signal pin, so one overlapping is calculated. Since the weight of the standard cell 340 is 2, one overlapping is multiplied by the weight 2, resulting in two overlappings.

In summary, if the overlapping condition of the via pillar arrangement set 310 with the plurality of standard cells 330, 340 is assigned as overlapping one signal pin, then the pin overlapping number of the via pillar arrangement set 310 with the standard cell 330 is two, the pin overlapping number of the via pillar arrangement set 310 with the standard cell 340 adjusted according to the weight 2 is four, and the total pin overlapping number of the via pillar arrangement set 310 with the plurality of standard cells 330, 340 is six.

In addition, referring to FIG. 16, the overlapping condition of the via pillar arrangement set 320 with the plurality of standard cells 330, 340 is assigned as overlapping one signal pin. As shown in the figure, the via pillar arrangement set 320 and the standard cell 330 overlap one signal pin, so one overlapping is calculated.

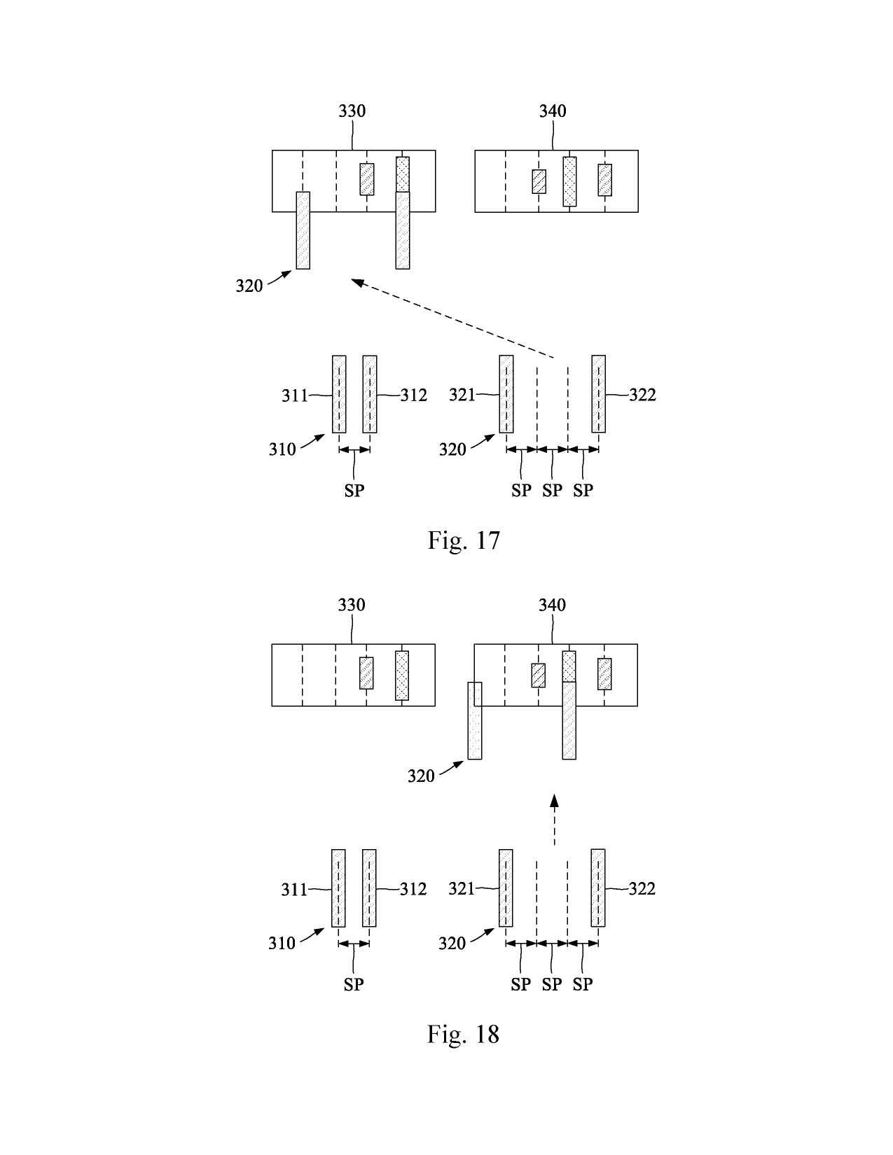

Referring to FIG. 17, the overlapping condition of the via pillar arrangement set 320 with the plurality of standard cells 330, 340 is still assigned as overlapping one signal pin. As shown in the figure, the via pillar arrangement set 320 and the standard cell 330 overlap one signal pin, so one overlapping is calculated.

Referring to FIG. 18, the overlapping condition of the via pillar arrangement set 320 with the plurality of standard cells 330, 340 is still assigned as overlapping one signal pin. As shown in the figure, the via pillar arrangement set 320 and the standard cell 340 overlap one signal pin, so one overlapping is calculated. Since the weight of the standard cell 340 is 2, one overlapping is multiplied by the weight 2, resulting in two overlappings.

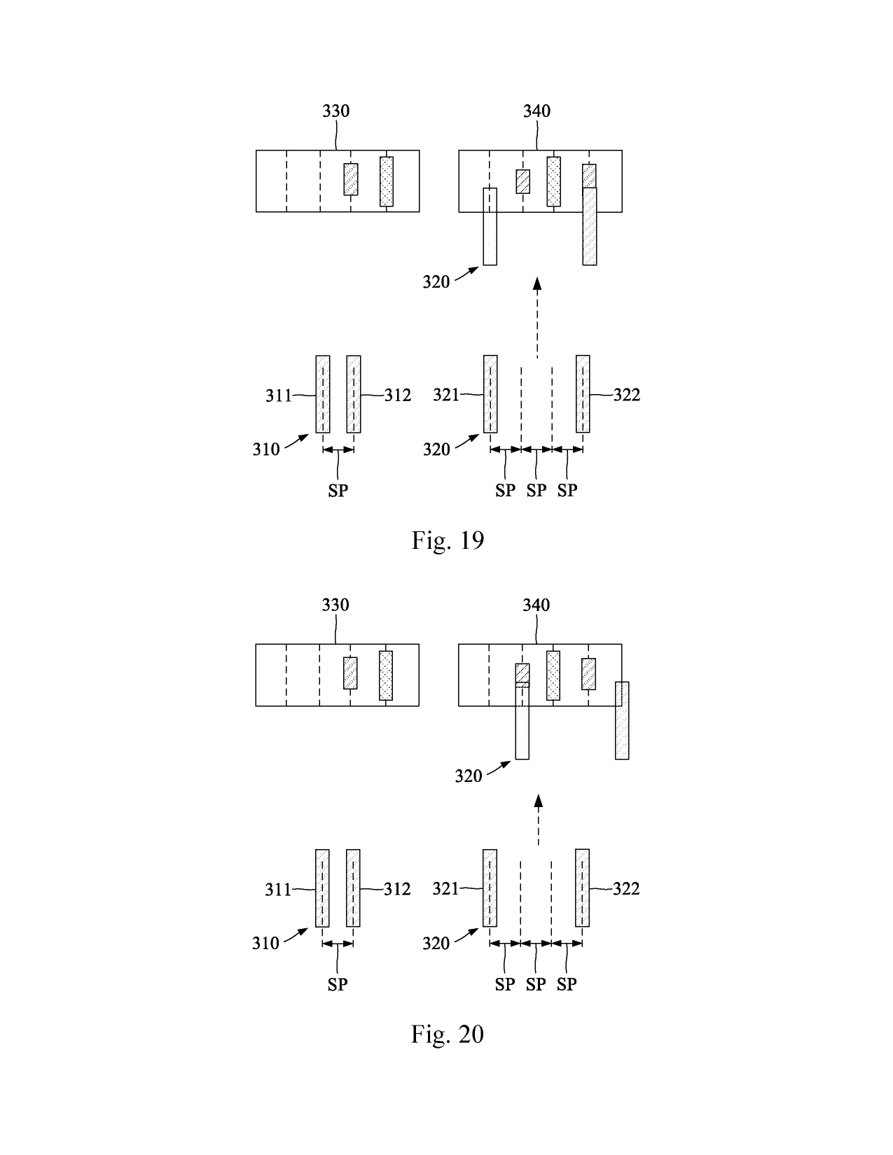

Referring to FIG. 19, the overlapping condition of the via pillar arrangement set 320 with the plurality of standard cells 330, 340 is still assigned as overlapping one signal pin. As shown in the figure, the via pillar arrangement set 320 and the standard cell 340 overlap one signal pin, so one overlapping is calculated. Since the weight of the standard cell 340 is 2, one overlapping is multiplied by the weight 2, resulting in two overlappings.

Referring to FIG. 20, the overlapping condition of the via pillar arrangement set 320 with the plurality of standard cells 330, 340 is still assigned as overlapping one signal pin. As shown in the figure, the via pillar arrangement set 320 and the standard cell 340 overlap one signal pin, so one overlapping is calculated. Since the weight of the standard cell 340 is 2, one overlapping is multiplied by the weight 2, resulting in two overlappings.

In summary, if the overlapping condition of the via pillar arrangement set 320 with the plurality of standard cells 330, 340 is assigned as overlapping one signal pin, then the pin overlapping number of the via pillar arrangement set 320 with the standard cell 330 is two, the pin overlapping number of the via pillar arrangement set 320 with the standard cell 340 adjusted according to the weight b is six, and the total pin overlapping number of the via pillar arrangement set 320 with the plurality of standard cells 330, 340 is eight.

Therefore, the pin overlapping number of the via pillar arrangement set 310 with the plurality of standard cells 330, 340 is six, while the pin overlapping number of the via pillar arrangement set 320 with the plurality of standard cells 330, 340 is eight. The circuit design method 200 of the present disclosure selects the via pillar arrangement set 310 corresponding to the minimum pin overlapping number as the target via pillar arrangement.

The aforementioned circuit design method 200 may be implemented as a computer program and stored in a non-transitory computer readable storage medium, so that after a computer reads the non-transitory computer readable storage medium, the computer executes the circuit design method 200. The non-transitory computer readable storage medium may be a read-only memory, a flash memory, a floppy disk, a hard disk, an optical disc, a flash drive, a magnetic tape, a database accessible through a network, or any computer readable storage medium having the same function that may be easily conceived by a person skilled in the art. The aforementioned circuit design method 200 may also be implemented by integrating the computer program with one or more processors or chips.

It should be noted that the present disclosure is not limited to the embodiments as shown in FIG. 1 to FIG. 20, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

Technical features of some embodiments of the present disclosure make an improvement to the prior art. During a power planning stage, the circuit design method, the circuit design device, and the non-transitory computer readable storage medium of the present disclosure may adopt a circuit design manner having lower obstruction to pin accessibility without needing to reduce a via pillar number, thereby increasing pin accessible area and routability during subsequent layout and routing stages. In addition, the circuit design method, the circuit design device, and the non-transitory computer readable storage medium of the present disclosure may provide a corresponding power planning manner according to different circuit designs.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A circuit design method, executed by a processor reading at least one command stored in a memory, comprising:
providing a plurality of via pillar arrangements, wherein each of the plurality of via pillar arrangements comprises a via pillar number and a via pillar spacing;
providing a plurality of standard cells;
calculating a plurality of pin overlapping numbers of each of the plurality of via pillar arrangements and the plurality of standard cells; and
selecting a via pillar arrangement corresponding to a minimum pin overlapping number among the plurality of pin overlapping numbers as a target via pillar arrangement.

2. The circuit design method of claim 1, further comprising:
determining whether the target via pillar arrangement conforms to a design rule; and
if the target via pillar arrangement conforms to the design rule, performing a circuit design by the target via pillar arrangement.

3. The circuit design method of claim 1, wherein the plurality of via pillar arrangements comprise a first via pillar arrangement set and a second via pillar arrangement set, and the plurality of pin overlapping numbers comprise a first pin overlapping number and a second pin overlapping number, wherein selecting the via pillar arrangement corresponding to the minimum pin overlapping number among the plurality of pin overlapping numbers as the target via pillar arrangement comprises:
comparing the first pin overlapping number between the first via pillar arrangement set and the plurality of standard cells with the second pin overlapping number between the second via pillar arrangement set and the plurality of standard cells; and
if the first pin overlapping number is smaller than the second pin overlapping number, selecting the first via pillar arrangement set corresponding to the first pin overlapping number as the target via pillar arrangement.

4. The circuit design method of claim 1, wherein the plurality of standard cells comprise a first standard cell and a second standard cell, wherein providing the plurality of standard cells comprises:
providing the first standard cell, wherein the first standard cell comprises a first weight; and
providing the second standard cell, wherein the second standard cell comprises a second weight.

5. The circuit design method of claim 4, wherein calculating the plurality of pin overlapping numbers of each of the plurality of via pillar arrangements and the plurality of standard cells comprises:
assigning an overlapping condition of each of the plurality of via pillar arrangements with the first standard cell and the second standard cell; and
calculating the plurality of pin overlapping numbers of each of the plurality of via pillar arrangements with the first standard cell and the second standard cell according to the overlapping condition, the first weight, and the second weight.

6. A circuit design device, comprising:
a memory, configured to store at least one command; and
a processor, configured to read the at least one command in the memory to execute:
providing a plurality of via pillar arrangements, wherein each of the plurality of via pillar arrangements comprises a via pillar number and a via pillar spacing;
providing a plurality of standard cells;
calculating a plurality of pin overlapping numbers of each of the plurality of via pillar arrangements and the plurality of standard cells; and
selecting a via pillar arrangement corresponding to a minimum pin overlapping number among the plurality of pin overlapping numbers as a target via pillar arrangement.

7. The circuit design device of claim 6, wherein the processor further reads the at least one command in the memory to execute:
determining whether the target via pillar arrangement conforms to a design rule; and
if the target via pillar arrangement conforms to the design rule, performing a circuit design by the target via pillar arrangement.

8. The circuit design device of claim 6, wherein the plurality of via pillar arrangements comprise a first via pillar arrangement set and a second via pillar arrangement set, and the plurality of pin overlapping numbers comprise a first pin overlapping number and a second pin overlapping number, wherein the processor further reads the at least one command in the memory to execute:
comparing the first pin overlapping number between the first via pillar arrangement set and the plurality of standard cells with the second pin overlapping number between the second via pillar arrangement set and the plurality of standard cells; and
if the first pin overlapping number is smaller than the second pin overlapping number, selecting the first via pillar arrangement set corresponding to the first pin overlapping number as the target via pillar arrangement.

9. The circuit design device of claim 6, wherein the plurality of standard cells comprise a first standard cell and a second standard cell, wherein the processor further reads the at least one command in the memory to execute:
providing the first standard cell, wherein the first standard cell comprises a first weight; and
providing the second standard cell, wherein the second standard cell comprises a second weight.

10. A non-transitory computer readable storage medium storing a computer program, wherein the computer program is configured to execute a circuit design method, and the circuit design method comprises:
providing a plurality of via pillar arrangements, wherein each of the plurality of via pillar arrangements comprises a via pillar number and a via pillar spacing;
providing a plurality of standard cells;
calculating a plurality of pin overlapping numbers of each of the plurality of via pillar arrangements and the plurality of standard cells; and
selecting a via pillar arrangement corresponding to a minimum pin overlapping number among the plurality of pin overlapping numbers as a target via pillar arrangement.
